(19) United States
(12) Patent Application Publication
(10) Pub. No.: US 2025/0176388 A1
(43) Pub. Date: May 29, 2025

(54) DISPLAY PANEL AND DISPLAY DEVICE

(71) Applicant: Yungu (Gu’an) Technology Co., Ltd., Langfang (CN)

(72) Inventors: Bo XIA, Langfang (CN); Sheng GUO, Langfang (CN); Miaomiao TIAN, Langfang (CN); Zhili MA, Langfang (CN)

(73) Assignee: Yungu (Gu’an) Technology Co., Ltd., Langfang (CN)

(21) Appl. No.: 19/035,955

(22) Filed: Jan. 24, 2025

(30) Foreign Application Priority Data
Feb. 29, 2024 (CN) 202410232463.4

(51) Int. Cl. H10K 59/131; H10K 59/121; H10K 59/122

(52) U.S. Cl. CPC H10K 59/131; H10K 59/122; H10K 59/1216

(57) ABSTRACT

Embodiments of the disclosure disclose a display panel and a display device. The display panel includes: a drive circuit layer; a pixel defining layer arranged on a side of the drive circuit layer, the pixel defining layer including a pixel opening; and a signal line layer arranged on a side of the pixel defining layer adjacent to the drive circuit layer. The signal line layer includes a conductive structure, which is arranged centrosymmetrically in the pixel opening. This embodiment provides a technical solution to the problem of dense signal lines in a limited space of a pixel on a display panel being likely to cause color deviation of light emitted by the pixel, which otherwise affects the display effect of the display panel.

### CROSS-REFERENCE TO RELATED APPLICATIONS

The present application claims priority to Chinese Patent Application No. 202410232463.4, filed on Feb. 29, 2024 and entitled “DISPLAY PANEL AND DISPLAY DEVICE”, which is incorporated herein by reference in its entirety.

### TECHNICAL FIELD

Embodiments of the disclosure relate to the technical field of displays, and in particular to a display panel and a display device.

### BACKGROUND ART

With the development of display technology, people have higher and higher requirements for display panels. Existing display panels have dense signal lines in a limited space of a pixel, affecting the display effect of the display panels.

### SUMMARY

Embodiments of that disclosure provide a display panel and a display device to solve the problem of dense signal lines in a limited space of a pixel on a display panel affecting the display effect of the display panel.

In order to solve the above technical problem, the disclosure adopts the following technical solutions.

An embodiment of the disclosure provides a display panel, including:
a drive circuit layer;
a pixel defining layer arranged on a side of the drive circuit layer, the pixel defining layer including a plurality of pixel openings; and
a signal line layer arranged on a side of the pixel defining layer adjacent to the drive circuit layer, wherein
the signal line layer includes a plurality of conductive structures;
and the conductive structure is arranged centrosymmetrically in the pixel opening.

Thanks to such an arrangement, a light exit region defined by the pixel opening is divided relatively uniformly into at least two regions by the conductive structure. Since the conductive structure is arranged centrosymmetrically in the pixel opening, the regions of the pixel opening divided by the conductive structure have similar areas and similar exit light intensities, thereby better improving the display effect of the display panel.

Optionally, an orthographic projection of the conductive structure on the drive circuit layer is located at least partially in an orthographic projection of the pixel opening on the drive circuit layer.

Optionally, the conductive structure is symmetric both in a first direction and in a second direction;
and the first direction intersects with the second direction.

Preferably, the first direction is perpendicular to the second direction.

Preferably, the display panel further includes a plurality of pixels, the drive circuit layer is connected to the plurality of pixels, and a light emitting layer of the pixel is arranged in the pixel opening; and the first direction is parallel to a row direction of the pixel and the second direction is parallel to a column direction of the pixel.

Optionally, the shape of the conductive structure includes an “I” shape, a hollow square shape, or an “H” shape.

By arranging the conductive structure to be symmetric both in the first direction and in the second direction, the luminous uniformity of the pixel is further improved and the color deviation of the display panel is further improved.

Optionally, the conductive structure includes at least two first conductive portions and a second conductive portion;
the second conductive portion is connected between the at least two first conductive portions;
an extension direction of the first conductive portions is different from an extension direction of the second conductive portion;
and the first conductive portions have a width less than a width of the second conductive portion.

Thanks to such an arrangement, the width of the second conductive portion connected between the first conductive portions is wider, so as to provide a shielding effect and reduce crosstalk between signal lines.

Preferably, the second conductive portion is arranged centrally in a region defined by the pixel opening.

Optionally, the display panel further includes a substrate, wherein the substrate is arranged on a side of the drive circuit layer away from the pixel defining layer; the drive circuit layer further includes:
a gate layer arranged on one side of the substrate; and
a capacitor layer arranged on a side of the gate layer away from the substrate; and
an orthographic projection of the second conductive portion on the substrate covers at least part of an orthographic projection of the capacitor layer on the substrate.

Such an arrangement can improve the potential stability of the capacitor layer and therefore the potential stability of the drive circuit layer, further improving the display effect of the display panel.

Optionally, the drive circuit layer further includes:
a gate bridge layer arranged on a side of the capacitor layer away from the substrate; and
the orthographic projection of the second conductive portion on the substrate covers at least part of an orthographic projection of the gate bridge layer on the substrate.

Preferably, the orthographic projection of the second conductive portion on the substrate covers the entire orthographic projection of the gate bridge layer on the substrate.

Thanks to such an arrangement, the orthographic projection of the second conductive portion on the substrate covers at least part of the orthographic projection of the gate bridge layer on the substrate, so that the second conductive portion can better shield an electrical signal coupled to the gate bridge layer, improving the potential stability of the gate bridge layer and therefore the potential stability of a gate of the drive circuit layer, thereby improving the display effect of the display panel.

Optionally, the signal line layer further includes:
a plurality of shield structures connected to the conductive structures;
and an orthographic projection of the shield structure on the substrate does not overlap with an orthographic projection of the pixel opening on the substrate.

Such an arrangement can further improve the shielding effect of the signal line layer, further improve the crosstalk of the drive circuit layer that is caused by the signal line layer or other layers of signal lines, and further improve the display effect of the display panel.

Preferably, the orthographic projection of the shield structure on the substrate covers at least part of the orthographic projection of the gate bridge layer on the substrate.

Optionally, the signal line layer further includes:
at least one data line arranged on at least one side of the conductive structure and/or the shield structure;
and the conductive structure and the shield structure are configured to transmit a power supply signal.

Preferably, a distance between the second conductive portion and the data line is greater than or equal to 2 μm and less than or equal to 4 μm.

Thanks to such an arrangement, the conductive structure and/or the shield structure can not only better prevent crosstalk of a gate of a drive transistor of the drive circuit layer that is caused by other signal lines, but can also better avoid the color deviation problem of light emitted by the pixel, further improving the display effect of the display panel.

Optionally, the display panel further includes a pixel, wherein the plurality of pixels includes a plurality of pairs of pixels, the pair of pixels including a first pixel and a second pixel having the same luminous color and arranged adjacent to each other;
the conductive structure includes a first conductive structure and a second conductive structure;
an orthographic projection of the first conductive structure on the drive circuit layer is located at least partially in an orthographic projection of the first pixel on the drive circuit layer;
an orthographic projection of the second conductive structure on the drive circuit layer is located at least partially in an orthographic projection of the second pixel on the drive circuit layer;
the first conductive structure and the second conductive structure are symmetrically arranged with respect to a first axis of symmetry; and the first axis of symmetry is a perpendicular bisector of a line segment connecting a center of the first pixel and a center of the second pixel.

Thanks to such an arrangement, the light emitted by the first pixel and the second pixel adjacent to each other can compensate for each other, to further improve the luminous uniformity of the pixel, thereby improving the display effect of the display panel.

Preferably, the first pixel and the second pixel are located in the same pixel row.

Preferably, the display panel further includes:
a plurality of third pixels having a luminous color different from the luminous color of the first pixel;
and a pixel column in which the third pixel is located is arranged between a pixel column in which the first pixel is located and a pixel column in which the second pixel is located.

Preferably, the luminous color of the first pixel and the second pixel is a first luminous color and the luminous color of the third pixel is a second luminous color;
and the first pixel and the second pixel are located in adjacent columns of pixel columns having the first luminous color.

Optionally, the second conductive portion of the first conductive structure includes a first sub-conductive portion and a second sub-conductive portion;
an orthographic projection of the first sub-conductive portion on the drive circuit layer is located in an orthographic projection of the first pixel of an n-th row on the drive circuit layer;
an orthographic projection of the second sub-conductive portion on the drive circuit layer is located in an orthographic projection of the first pixel of an (n+1)-th row on the drive circuit layer;
where n is a positive integer greater than or equal to 1;
preferably, when the first sub-conductive portion is arranged centrally in a region defined by the pixel opening, the second sub-conductive portion is arranged centrally in the region defined by the pixel opening;
when the first sub-conductive portion is arranged on the left in the region defined by the pixel opening, the second sub-conductive portion is arranged on the right in the region defined by the pixel opening; and
when the first sub-conductive portion is arranged on the right in the region defined by the pixel opening, the second sub-conductive portion is arranged on the left in the region defined by the pixel opening.

According to another aspect of the disclosure, an embodiment provides a display panel, including:
a drive circuit layer;
a pixel defining layer arranged on a side of the drive circuit layer, the pixel defining layer including a plurality of pixel openings; and
a signal line layer arranged on a side of the pixel defining layer adjacent to the drive circuit layer, wherein
the signal line layer includes a plurality of conductive structures;
the conductive structure divides the pixel opening into at least two light exit areas in the pixel opening; and exit light intensities of the light exit areas on two sides of the conductive structure are balanced in a preset direction.

According to a further aspect of the disclosure, an embodiment provides a display device including a display panel according to any of the items of the first aspect, or a display panel according to any of the items of the second aspect.

In the display panel according to this embodiment, a signal line layer is arranged between a drive circuit layer and a pixel defining layer, the signal line layer includes a plurality of conductive structures, and the conductive structure is arranged centrosymmetrically in the pixel opening. Thanks to such an arrangement, a light exit region defined by the pixel opening is divided relatively uniformly into at least two regions by the conductive structure. Since the conductive structure is centrosymmetric in the pixel opening, the regions of the pixel opening divided by the conductive structure have similar areas and similar exit light intensities, thereby better improving the display effect of the display panel.

### BRIEF DESCRIPTION OF THE DRAWINGS

In order to describe the technical solutions in the embodiments of the disclosure more clearly, the accompanying drawings that are required for describing the embodiments of the disclosure will be briefly introduced below. Apparently, the accompanying drawings in the following description are merely for some embodiments of the disclosure, and for those of ordinary skill in the art, other drawings would also have been obtained from the contents of the embodiments of the disclosure and these accompanying drawings without involving any inventive effort.

FIG. 1 is a schematic structural diagram of a display panel according to an embodiment of the disclosure;

FIG. 2 is a schematic structural diagram of another display panel according to an embodiment of the disclosure;

FIG. 3 is a schematic structural diagram of still another display panel according to an embodiment of the disclosure;

FIG. 4 is a schematic structural diagram of yet another display panel according to an embodiment of the disclosure;

FIG. 5 is a schematic structural diagram of a further display panel according to an embodiment of the disclosure;

FIG. 6 is a schematic structural diagram of a still further display panel according to an embodiment of the disclosure;

FIG. 7 is a schematic structural diagram of a yet further display panel according to an embodiment of the disclosure;

FIG. 8 is a schematic structural diagram of another display panel according to an embodiment of the disclosure;

FIG. 9 is a schematic structural diagram of still another display panel according to an embodiment of the disclosure;

FIG. 10 is a schematic structural diagram of yet another display panel according to an embodiment of the disclosure; and

FIG. 11 is a schematic structural diagram of a display device according to an embodiment of the disclosure.

### DETAILED DESCRIPTION OF EMBODIMENTS

The disclosure is to be further in detail below with reference to the drawings and embodiments. It can be understood that specific embodiments described herein are used merely to explain the disclosure, rather than limit the disclosure. It should be additionally noted that, for ease of description, only some but not all structures related to the disclosure are shown in the drawings.

Based on the technical problem described above, the present embodiment proposes the following solutions.

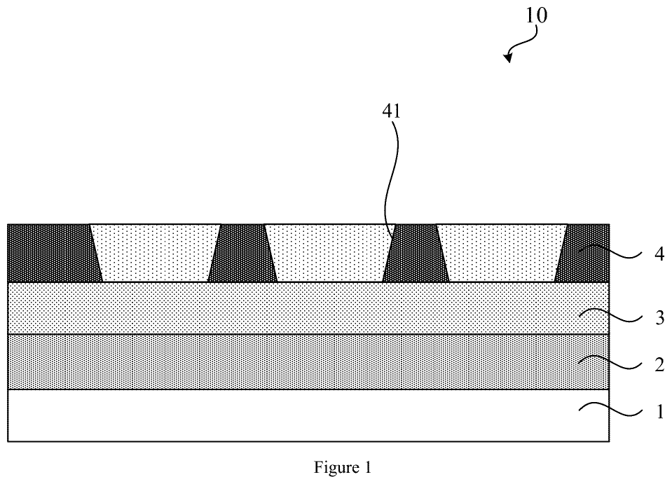

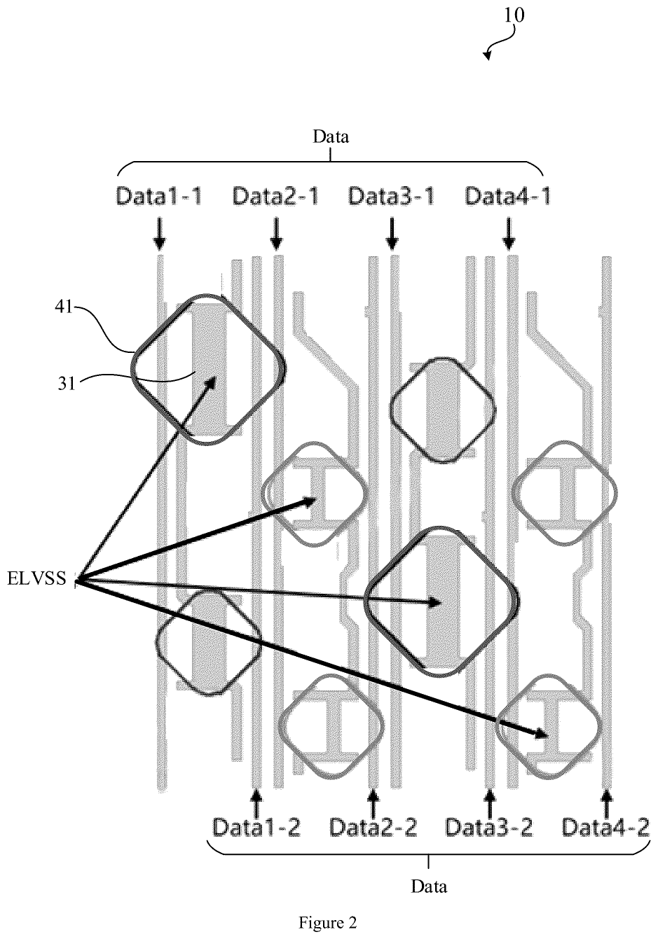

FIG. 1 is a schematic structural diagram of a display panel according to an embodiment of the disclosure. FIG. 2 is a schematic structural diagram of another display panel according to an embodiment of the disclosure. With respect to FIGS. 1 and 2, an embodiment of the disclosure provides a display panel 10 including: a drive circuit layer 2; a pixel defining layer 4 arranged on a side of the drive circuit layer 2, the pixel defining layer 4 including a pixel opening 41; and a signal line layer 3 arranged on a side of the pixel defining layer 4 adjacent to the drive circuit layer 2. The signal line layer 3 includes a plurality of conductive structures 31, the conductive structure 31 being arranged centrosymmetrically in the pixel opening 41.

Specifically, a substrate 1 includes a silicon substrate, a sapphire substrate, a glass substrate, etc. The display panel 10 includes a plurality of pixels. The drive circuit layer 2 is used to drive the pixels to emit light. The pixel defining layer 4 includes a plurality of pixel openings 41. The pixel defining layer 4 includes the pixel openings 41 that are through holes. The pixel may include an anode layer on the side close to the substrate 1 and a cathode layer on the side away from the substrate 1. The pixel may further include a light emitting layer arranged between the anode layer and the cathode layer.

The signal line layer 3 is arranged between the drive circuit layer 2 and the pixel defining layer 4. The signal line layer 3 may include signal lines such as power lines ELVSS and data lines Data. A low-level power supply signal may be transmitted in the power line ELVSS. Specifically, the conductive structure 31 may transmit the power supply signal, such as a low-level power supply signal.

It should be noted that the FIG. 2 only shows, by way of example, the case where the signal line layer 3 includes data lines Data and power lines ELVSS, and the signal line layer 3 may further include other signal lines, which are not limited herein. FIG. 2 shows, by way of example, the case where each power line ELVSS corresponds to two data lines Data, which is not limited herein.

By way of example, referring to FIG. 2, a first data line Data1-1 in a first column and a second data line Data1-2 in the first column correspond to the same power line ELVSS. A first data line Data2-1 in a second column and a second data line Data2-2 in the second column correspond to a further power line ELVSS. A first data line Data3-1 in a third column and a second data line Data3-2 in the third column correspond to a still further power line ELVSS. A first data line Data4-1 in a fourth column and a second data line Data4-2 in the fourth column correspond to a yet further power line ELVSS.

It should be noted that a pixel with a blue luminous color is correspondingly arranged in a blue pixel opening in the figure. A pixel with a red luminous color is correspondingly arranged in a red pixel opening in the figure. A pixel with a green luminous color is correspondingly arranged in a green pixel opening in the figure. The arrangement of pixels of various colors is not limited in any way, and FIG. 2 shows only one of the arrangements by way of example, not by way of limitation.

Since the material of the conductive structure 31 is generally a metal conductor made of, for example, Ti, Al, Ti—Al—Ti alloy, etc. The conductive structure 31 has poor light transmittance. The conductive structure 31 is arranged centrosymmetrically in the opening, so that the light exit regions on two sides of the conductive structure 31 corresponding to the pixel opening 41 are relatively balanced, effectively improving the luminous uniformity of the pixel, and improving the color deviation of the display panel 10.

In the display panel 10 according to this embodiment, the signal line layer 3 is arranged between the drive circuit layer 2 and the pixel defining layer 4. The signal line layer 3 includes the conductive structure 31. The conductive structure 31 is arranged centrosymmetrically in the pixel opening 41. Thanks to such an arrangement, a light exit region defined by the pixel opening 41 is divided relatively uniformly into at least two regions by the conductive structure 31. Since the conductive structure 31 is arranged centrosymmetrically in the pixel opening 41, the regions of the pixel opening 41 divided by the conductive structure 31 have similar areas and similar exit light intensities, thereby better improving the display effect of the display panel 10.

It should be noted that the conductive structure 31 being centrosymmetric in the pixel opening means that the conductive structure 31 is arranged completely centrosymmetrically in the pixel opening. It is also possible that the conductive structure 31 tends to be arranged centrosymmetrically in the pixel opening 41, which is not limited herein.

Optionally, on the basis of the above embodiments, still referring to FIGS. 1 and 2, an orthographic projection of the conductive structure 31 on the drive circuit layer 2 is located at least partially in an orthographic projection of the pixel opening 41 on the drive circuit layer 2.

Specifically, thanks to such an arrangement, the orthographic projection of the conductive structure 31 of the signal line layer 3 on the drive circuit layer 2 is aligned with the orthographic projection of the pixel opening 41 on the drive circuit layer 2, so that the light exited on the two sides of or around the conductive structure 31 in the pixel opening 41 is more uniform, further improving the display effect of the display panel.

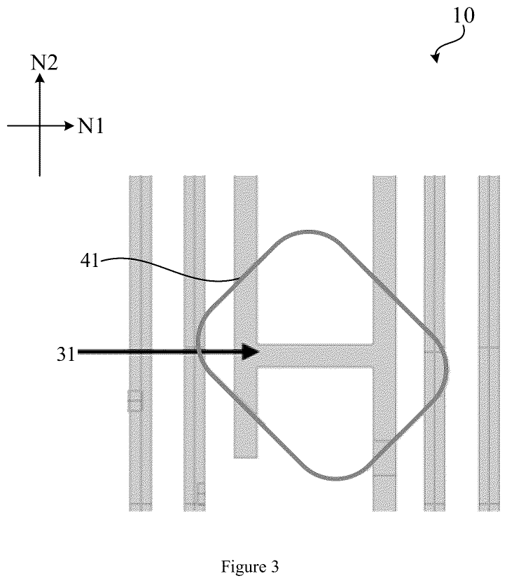

Optionally, FIG. 3 is a schematic structural diagram of yet another display panel according to an embodiment of the disclosure. On the basis of the above embodiments, referring to FIG. 3, the conductive structure 31 is symmetric both in a first direction N1 and in a second direction N2. The first direction N1 intersects with the second direction N2. Preferably, the first direction N1 is perpendicular to the second direction N2.

Optionally, the display panel 10 further includes a pixel, the drive circuit layer 2 is connected to the pixel, and a light emitting layer of the pixel is arranged in the pixel openings 41. The first direction N1 is parallel to a row direction of the pixel and the second direction N2 is parallel to a column direction of the pixel.

Optionally, the shape of the conductive structure includes an “I” shape, a hollow square shape, or an “H” shape.

Specifically, thanks to such an arrangement, the conductive structure 31 is symmetric in both the first direction N1 and the second direction N2, so that the pixel emits more uniform light. Since the method for compensating the luminous brightness of the display panel 10 is generally performed in the row direction and the column direction of the pixel, by arranging the conductive structure 31 to be symmetric both in the first direction N1 and in the second direction N2, the luminous uniformity of the pixel is further improved and the color deviation of the display panel 10 is further improved.

It should be noted that FIG. 3 shows, by way of example, the case where the conductive structure 31 is “H”-shaped, which is not limited herein.

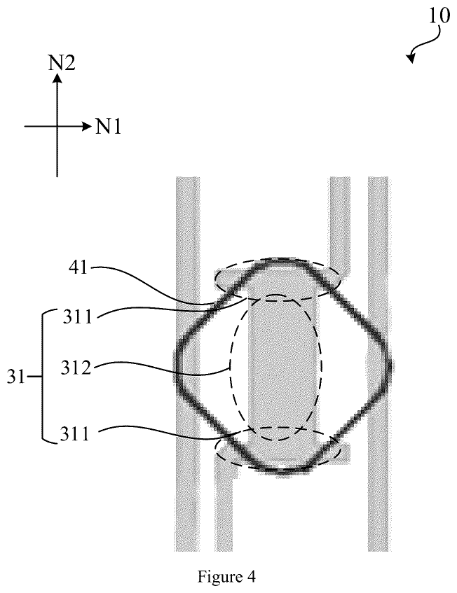

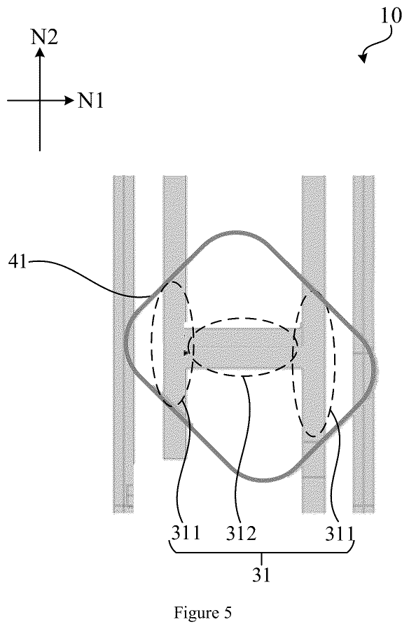

Optionally, FIG. 4 is a schematic structural diagram of yet another display panel according to an embodiment of the disclosure. FIG. 5 is a schematic structural diagram of a further display panel according to an embodiment of the disclosure. On the basis of the above embodiments, in conjunction with FIGS. 4 and 5, the conductive structure 31 may include at least two first conductive portions 311 and a second conductive portion 312. The second conductive portion 312 is connected between the at least two first conductive portions 311. An extension direction of the first conductive portions 311 is different from an extension direction of the second conductive portion 312. The first conductive portions 311 have a width less than a width of the second conductive portion 312.

Specifically, referring to FIG. 4, it is possible to configure the first conductive portion 311 to extend in the first direction N1 and the second conductive portion 312 to extend in the second direction N2. Alternatively, referring to FIG. 5, it is possible to configure the first conductive portion 311 to extend in the second direction N2 and the first conductive portion 311 to extend in the first direction N1. Thanks to that the first conductive portions 311 have a width less than a width of the second conductive portion 312, the width of the second conductive portion 312 connected between the first conductive portions 311 is wider, so as to provide a shielding effect and reduce crosstalk between signal lines.

It should be noted that FIG. 4 shows, by way of example, the case where the conductive structure 31 is “I”-shaped, and FIG. 5 shows, by way of example, the case where the conductive structure 31 is “H”-shaped, which is not limited herein.

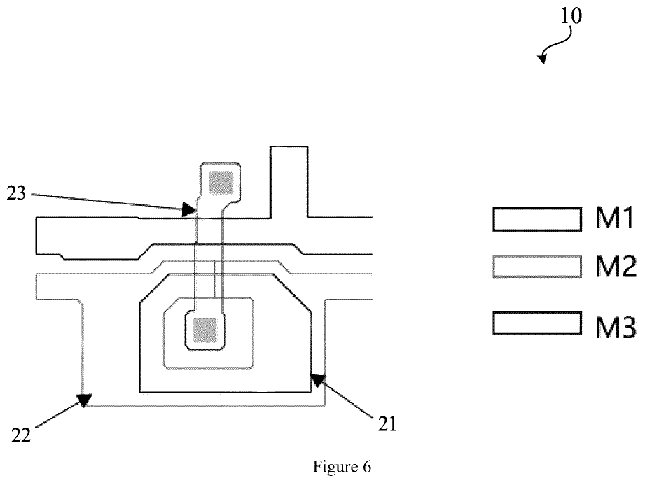

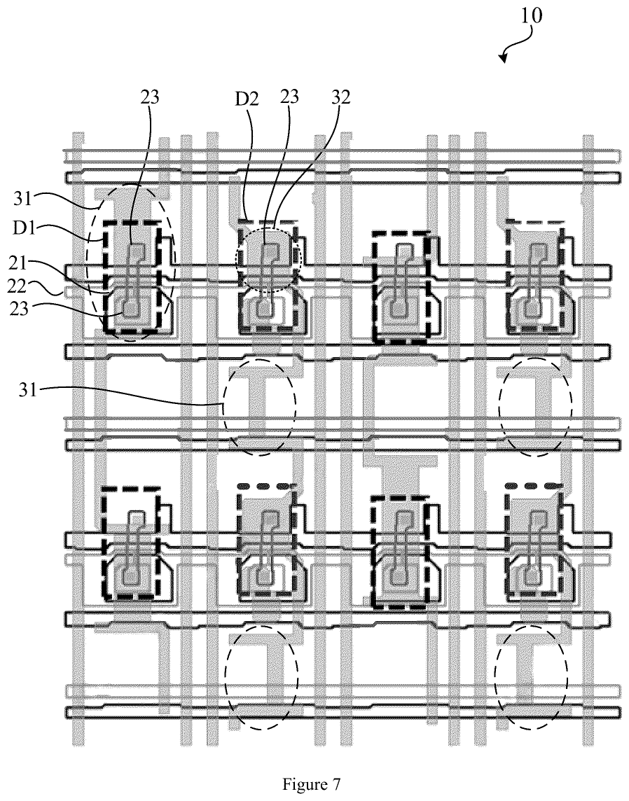

Optionally, FIG. 6 is a schematic structural diagram of a still further display panel according to an embodiment of the disclosure. FIG. 7 is a schematic structural diagram of a yet further display panel according to an embodiment of the disclosure. On the basis of the above embodiments, with respect to FIGS. 1, 6 and 7, optionally, the display panel 10 further includes a substrate 1. The substrate 1 is arranged on a side of the drive circuit layer 2 away from the pixel defining layer 4. The drive circuit layer 2 may further include: a gate layer 21 arranged on one side of the substrate 1; and a capacitor layer 22 arranged on a side of the gate layer 21 away from the substrate 1. An orthographic projection of the second conductive portion 312 on the substrate 1 covers at least part of an orthographic projection of the capacitor layer 22 on the substrate 1.

Specifically, thanks to such an arrangement, the second conductive portion 312 with a fixed potential can better shield the crosstalk between signal lines. By configuring the orthographic projection of the second conductive portion 312 on the substrate 1 to cover at least part of the orthographic projection of the capacitor layer 22 on the substrate 1, other signal lines such as the data lines Data of the signal line layer 3 cannot be coupled to the capacitor layer 22 in the direction of the substrate 1, thereby improving the potential stability of the capacitor layer 22 and therefore the potential stability of the drive circuit layer 2, and further improving the display effect of the display panel 10.

It should be noted that FIG. 6 shows, by way of example, that the drive circuit layer 2 includes a first conductive layer M1, a second conductive layer M2 and a third conductive layer M3 which are laminated on one side of the substrate 1. The capacitor layer includes a first capacitor layer and a second capacitor layer. The gate layer 21 and the first capacitor layer are located at the first conductive layer M1. The second capacitor layer is located at the second conductive layer M2.

It should be noted that a first region D1 and a second region D2 are shown in FIG. 7 by way of example. The first region D1 corresponds to the position of the pixel opening. The second region D2 is not arranged corresponding to the pixel opening. The orthographic projection of the second conductive portion 312 of the conductive structure 31 in the first region D1 on the substrate 1 covers at least part of the orthographic projection of the capacitor layer 22 on the substrate 1.

Optionally, on the basis of the above embodiments, still referring to FIG. 6, the drive circuit layer 2 may further include: a gate bridge layer 23 arranged on a side of the capacitor layer 22 away from the substrate 1. The orthographic projection of the second conductive portion 312 on the substrate 1 covers at least part of an orthographic projection of the gate bridge layer 23 on the substrate 1. Preferably, the orthographic projection of the second conductive portion 312 on the substrate 1 covers the entire orthographic projection of the gate bridge layer 23 on the substrate 1.

Specifically, the gate bridge layer 23 is used to bridge a gate of a drive transistor included in the drive circuit layer 2 to other layers, in order to electrically connect the gate to other switch transistors of a drive circuit. The orthographic projection of the second conductive portion 312 on the substrate 1 is configured to at least partially cover the orthographic projection of the gate bridge layer 23 on the substrate 1, so that the second conductive portion 312 can better shield an electrical signal coupled to the gate bridge layer 23, improving the potential stability of the gate bridge layer 23 and therefore the potential stability of a gate of the drive circuit layer 2, thereby improving the display effect of the display panel 10. The configuration of the orthographic projection of the second conductive portion 312 on the substrate 1 to completely cover the orthographic projection of the gate bridge layer 23 on the substrate 1 further improves the potential stability of the gate of the drive circuit layer 2, thereby further improving the display effect of the display panel 10.

It should be noted that FIG. 6 shows, by way of example, that the gate bridge layer 23 is located at the third conductive layer M3. The case where the second capacitor layer is located at the second conductive layer M2 is not limited herein.

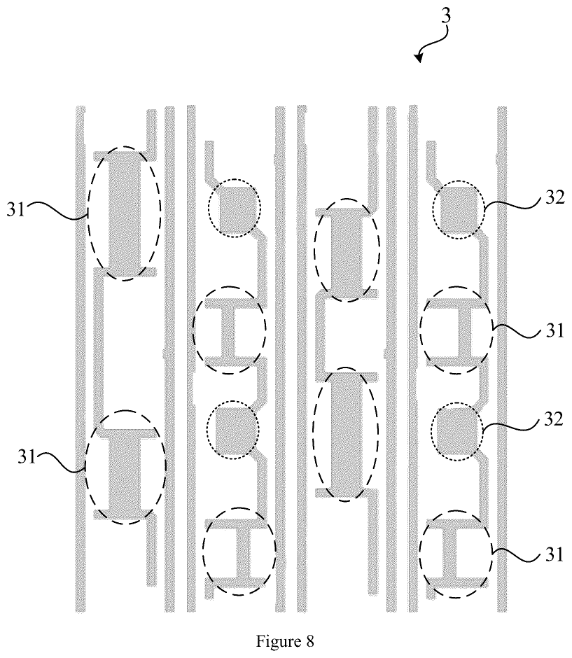

Optionally, FIG. 8 is a schematic structural diagram of another display panel according to an embodiment of the disclosure. On the basis of the above embodiments, still referring to FIGS. 6 to 8, the signal line layer 3 may further include: a plurality of shield structures 32. The shield structure 32 is connected to the conductive structures 31; and an orthographic projection of the shield structure 32 on the substrate 1 does not overlap with an orthographic projection of the pixel opening 41 on the substrate 1, i.e. the orthographic projections of the two are arranged offset from each other.

Specifically, the shield structure 32 does not correspond to the pixel opening 41. The shield structure 32 is electrically connected to the conductive structure 31, that is, the shield structure 32 and the conductive structure 31 are different parts of the same signal line. By configuring the signal line layer 3 to further include the shield structure 32, the shielding effect of the signal line layer 3 can be further improved, and the crosstalk of the drive circuit layer 2 that is caused by the signal line layer 3 or other layers of signal lines can be further improved.

It should be noted that FIG. 7 shows, by way of example, that the second region D2 does not correspond to the pixel opening. The shield structure 32 is arranged in the second region D2. The orthographic projection of the shield structure 32 on the substrate 1 is offset from the orthographic projection of the pixel opening 41 on the substrate 1. FIG. 8 schematically shows the layout of the signal line layer 3 and shows, by way of example, the conductive structure 31 and the shield structure 32.

Optionally, on the basis of the above embodiments, and still referring to FIGS. 6 to 8, the orthographic projection of the shield structure 32 on the substrate 1 covers at least part of the orthographic projection of the gate bridge layer 23 on the substrate 1.

Specifically, thanks to such an arrangement, the gate bridge layer 23, which is offset from the pixel openings 41, is shielded from signals by the shield structure 32, further enabling each drive circuit of the drive circuit layer 2 to avoid signal crosstalk, thereby improving the display effect of the display panel 10.

Optionally, on the basis of the above embodiments, and still referring to FIGS. 2 and 4, the second conductive portion 312 is arranged centrally in the region defined by the pixel opening 41.

Specifically, thanks to such an arrangement, the second conductive portion 312 can not only better shield the capacitor layer 22, the gate bridge layer 23 or the like of the pixel circuit layer from signals, but can also maintain a relatively uniform distance between the second conductive portion 312 and the data lines Data or the like of the same layer, thereby better avoiding crosstalk between the second conductive portion 312 and adjacent signal lines such as the data lines Data. Moreover, the second conductive portion 312 is arranged centrally in the region defined by the pixel opening 41, so that relatively uniform light is exited in the pixel opening 41, thereby improving the color deviation of the display panel 10, and further improving the display effect of the display panel 10.

It can be understood that if there is no capacitor layer 22 or no gate bridge layer 23 in a direction perpendicular to the display panel 10 in the region where the second conductive portion 312 is located, the width of the second conductive portion 312 can be adaptively reduced, and can be set according to the actual situation.

Optionally, on the basis of the above embodiments, still referring to FIG. 2, the signal line layer 3 may further include: at least one data line Data. The at least one data line Data is arranged on at least one side of the conductive structure 31 and/or the shield structure 32. The conductive structure 31 and the shield structure 32 are configured to transmit a power supply signal. Preferably, a distance between the second conductive portion 312 and the data line Data is greater than or equal to 2 μm and less than or equal to 4 μm. Specifically, the distance between the second conductive portion 312 and the data line Data may be 2 μm, 2.5 μm, 3 μm, 3.5 μm or 4 μm. This can be set according to the actual situation.

Specifically, the conductive structure 31 and the shield structure 32 may be parts of the structure of the power line ELVSS. The conductive structure 31 and the shield structure 32 may be used to transmit a power supply signal. Within a single pixel unit, it may be provided that each power line ELVSS corresponds to one data line Data, or each power line ELVSS corresponds to two data lines Data. The power line ELVSS may transmit a level signal, such as low-level signal. The power line ELVSS is routed in the display area and is provided with a conductive structure 31 which is aligned with the pixel opening 41. The power line ELVSS may also be provided with a shield structure 32 which does not correspond to the pixel opening 41. Thanks to such an arrangement, the power line ELVSS can not only better prevent crosstalk of the gate of the drive transistor of the drive circuit layer 2 that is caused by other signal lines, but can also better avoid the color deviation problem of light emitted by the pixel, further improving the display effect of the display panel 10.

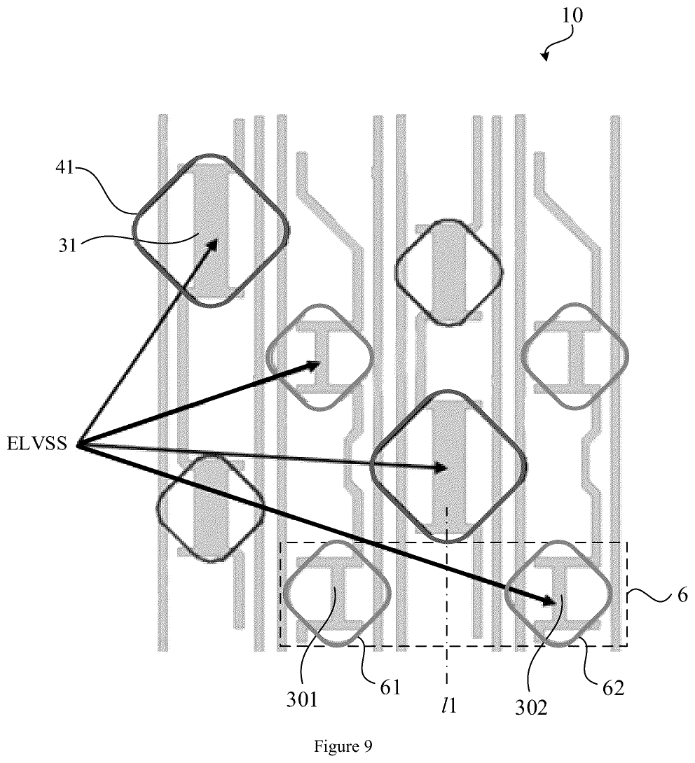

Optionally, FIG. 9 is a schematic structural diagram of still another display panel according to an embodiment of the disclosure. On the basis of the above embodiments, referring to FIG. 9, the plurality of pixels includes a plurality of pairs of pixels 6, the pair of pixels 6 including a first pixel 61 and a second pixel 62 having the same luminous color and arranged adjacent to each other. The conductive structure 31 includes a first conductive structure 301 and a second conductive structure 302. An orthographic projection of the first conductive structure 301 on the drive circuit layer 2 is located at least partially in an orthographic projection of the first pixel 61 on the drive circuit layer 2. An orthographic projection of the second conductive structure 302 on the drive circuit layer 2 is located at least partially in an orthographic projection of the second pixel 62 on the drive circuit layer 2. The first conductive structure 301 and the second conductive structure 302 are symmetrically arranged with respect to a first axis of symmetry 11. The first axis of symmetry 11 is a perpendicular bisector of a line segment connecting a center of the first pixel 61 and a center of the second pixel 62.

Specifically, the first pixel 61 and the second pixel 62 are located in the same pixel row. The first pixel 61 and the second pixel 62 are arranged symmetrically with respect to the first axis of symmetry 11. By way of example, the first pixel 61 and the second pixel 62 may have the same luminous color, and, for example, are both green pixels. The pixel openings 41 of the first pixel 61 and the second pixel 62 are not aligned with either the gate bridge layer 23 or the capacitor layer 22. The orthographic projection of the first conductive structure 301 on the substrate 1 is located at least partially in the orthographic projection of the first pixel 61 on the substrate 1. The orthographic projection of the second conductive structure 302 on the substrate 1 is located at least partially in the orthographic projection of the second pixel 62 on the substrate 1. Thanks to that the first conductive structure 301 and the second conductive structure 302 are arranged symmetrically with respect to the first axis of symmetry 11, the light emitted by the first pixel 61 and the second pixel 62 adjacent to each other can compensate for each other, to further improve the luminous uniformity of the pixel, thereby improving the display effect of the display panel 10.

It should be noted that the conductive structure may tend to be arranged centrosymmetrically in the pixel opening. FIG. 9 shows, by way of example, the case where the luminous colors of the first pixel and the second pixel included in the pair of pixels 6 are both green, which is not limited herein. In conjunction with FIGS. 4 and 9, when neither the second conductive portion 312 of the first conductive structure 301 nor the second conductive portion 312 of the second conductive structure 302 is exactly in the middle of the pixel opening, the first conductive structure 301 and the second conductive structure 302 may be arranged symmetrically with respect to the first axis of symmetry 11, so that the light emitted by the first pixel 61 and the second pixel 62 adjacent to each other can compensate for each other, to further improve the luminous uniformity of the pixel, thereby improving the display effect of the display panel 10.

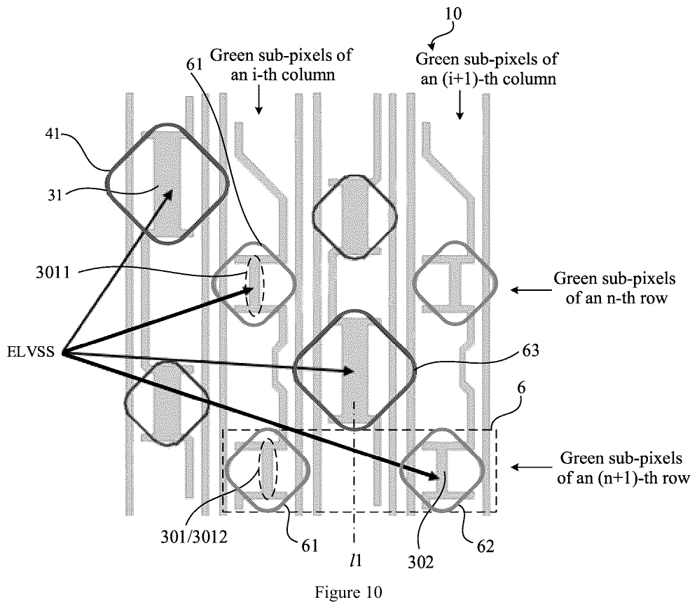

Optionally, FIG. 10 is a schematic structural diagram of yet another display panel according to an embodiment of the disclosure. On the basis of the above embodiments, referring to FIG. 10, the display panel 10 may further include a plurality of third pixels 63, the luminous color of the third pixel 63 having a luminous color different from the luminous color of the first pixel 61; and a pixel column in which the third pixel 63 is located is arranged between a pixel column in which the first pixel 61 is located and a pixel column in which the second pixel 62 is located.

Specifically, the third pixel 63 may be a blue sub-pixel and/or a red sub-pixel.

Optionally, on the basis of the above embodiments, still referring to FIG. 10, the luminous color of the first pixel 61 and the second pixel 62 is a first luminous color, and the luminous color of the third pixel 63 is a second luminous color; and the first pixel 61 and the second pixel 62 are located in adjacent columns of pixel columns having the first luminous color.

Optionally, on the basis of the above embodiments, still referring to FIG. 10, the second conductive portion 312 of the first conductive structure 301 includes a first sub-conductive portion 3011 and a second sub-conductive portion 3012; an orthographic projection of the first sub-conductive portion 3011 on the drive circuit layer is located in an orthographic projection of the first pixel 61 of an n-th row on the drive circuit layer; and an orthographic projection of the second sub-conductive portion 3012 on the drive circuit layer is located in an orthographic projection of the first pixel 61 of an (n+1)-th row on the drive circuit layer, where n is a positive integer greater than or equal to 1. The value of n may be 1, 2, 3, 4, etc.

Preferably, when the first sub-conductive portion 3011 is arranged centrally in a region defined by the pixel opening 41, the second sub-conductive portion 3012 is arranged centrally in the region defined by the pixel opening 41; when the first sub-conductive portion 3011 is arranged on the left in the region defined by the pixel opening 41, the second sub-conductive portion 3012 is arranged on the right in the region defined by the pixel opening 41; and when the first sub-conductive portion 3011 is arranged on the right in the region defined by the pixel opening 41, the second sub-conductive portion 3012 is arranged on the left in the region defined by the pixel opening 41. It should be noted that FIG. 10 shows, by way of example, the case where when the first sub-conductive portion 3011 is arranged on the left in the region defined by the pixel opening 41, the second sub-conductive portion 3012 is arranged on the right in the region defined by the pixel opening 41, which is not limited herein.

Further, it may be also provided that the second conductive portions 312 corresponding to two adjacent pixel openings of the same luminous color in the same column deviate from the centers of the pixel openings in opposite directions, when neither the second conductive portion 312 of the first conductive structure 301 nor the second conductive portion 312 of the second conductive structure 302 is in the middle of the pixel opening. By way of example, still referring to FIG. 10, for a sub-pixel of the first luminous color, e.g., a green sub-pixel, in the (i+1)-th column, when the second conductive portion 312 corresponding to the pixel opening in the n-th row deviates from the center of the pixel opening to the right, the second conductive portion 312 corresponding to the pixel opening in the (n+1)-th row deviates from the center of the pixel opening to the left, where i is a positive integer greater than or equal to 1. The value of i may be 1, 2, 3, 4, etc.

Specifically, thanks to such an arrangement, the light emitted by the first pixel 61 and the second pixel 62 of adjacent rows or columns can compensate for each other, to further improve the luminous uniformity of the pixel, thereby improving the display effect of the display panel 10.

It should be noted that FIG. 10 shows, by way of example, the positional relationship of pixel openings 41 corresponding to the light emitting layers of the green sub-pixel of the i-th column, the green sub-pixel of the (i+1)-th column, the green sub-pixel of the n-th row and the green sub-pixel of the (n+1)-th row, which is not limited herein.

In an optional implementation, an embodiment provides yet another display panel. On the basis of the above embodiments, and still referring to FIGS. 1 and 2, the display panel according to this embodiment includes: a drive circuit layer 2; a pixel defining layer 4 arranged on a side of the drive circuit layer 2, the pixel defining layer 4 including a plurality of pixel openings 41; and a signal line layer 3 arranged on a side of the pixel defining layer 4 adjacent to the drive circuit layer 2. The signal line layer 3 includes a plurality of conductive structures 31; and the conductive structure 31 divides the pixel opening 41 into at least two light exit areas in the pixel opening 41. Exit light intensities of the light exit areas on two sides of the conductive structure 31 are balanced in a preset direction.

Specifically, thanks to such an arrangement, the pixel opening 41 is divided by the conductive structure 31 into at least two light exit areas, and the light exit areas of the pixel opening 41 divided by the conductive structure 31 have similar areas and similar exit light intensities, so that the exit light intensity of the pixel opening 41 in the preset direction is balanced, thereby better improving the display effect of the display panel 10.

It should be noted that the preset direction may be set according to the requirements such as the arrangement of pixels and the display frame of pixels, such as the row direction or column direction of pixels, the direction perpendicular to the display panel or another light exit direction, which is not limited herein.

Optionally, an orthographic projection of the conductive structure 31 on the drive circuit layer 2 is located at least partially in an orthographic projection of the pixel opening 41 on the drive circuit layer 2.

Optionally, the conductive structure 31 is symmetric both in a first direction N1 and in a second direction N2. The first direction N1 intersects with the second direction N2. Preferably, the first direction N1 is perpendicular to the second direction N2.

Preferably, the display panel 10 further includes a pixel, the drive circuit layer 2 is connected to the pixel, and a light emitting layer of the pixel is arranged in the pixel openings 41. The first direction N1 is parallel to a row direction of the pixel and the second direction N2 is parallel to a column direction of the pixel.

Optionally, the shape of the conductive structure 31 includes an “I” shape, a hollow square shape, or an “H” shape.

Optionally, referring to FIGS. 4 and 5, the conductive structure 31 includes at least two first conductive portions 311 and a second conductive portion 312. The second conductive portion 312 is connected between the at least two first conductive portions 311. An extension direction of the first conductive portions 311 is different from an extension direction of the second conductive portion 312. The first conductive portions 311 have a width less than a width of the second conductive portion 312.

Preferably, the second conductive portion 312 is arranged centrally in a region defined by the pixel opening 41.

Optionally, in conjunction with FIGS. 1, 6 and 7, the display panel 10 further includes a substrate 1. The substrate 1 is arranged on a side of the drive circuit layer 2 away from the pixel defining layer 4. The drive circuit layer 2 further includes: a gate layer 21 arranged on one side of the substrate 1; and a capacitor layer 22 arranged on a side of the gate layer 21 away from the substrate. An orthographic projection of the second conductive portion 312 on the substrate 1 covers at least part of an orthographic projection of the capacitor layer 22 on the substrate 1.

Optionally, the drive circuit layer 2 further includes: a gate bridge layer 23 arranged on a side of the capacitor layer 22 away from the substrate. The orthographic projection of the second conductive portion 312 on the substrate 1 covers at least part of an orthographic projection of the gate bridge layer 23 on the substrate 1.

Preferably, the orthographic projection of the second conductive portion 312 on the substrate 1 covers the entire orthographic projection of the gate bridge layer 23 on the substrate 1.

Optionally, the signal line layer 3 further includes a plurality of shield structures 32. The shield structure 32 is connected to the conductive structure 31; and an orthographic projection of the shield structure 32 on the substrate 1 does not overlap with an orthographic projection of the pixel opening 41 on the substrate 1.

Preferably, the orthographic projection of the shield structure 32 on the substrate 1 covers at least part of the orthographic projection of the gate bridge layer 23 on the substrate 1.

Optionally, the signal line layer 3 further includes: at least one data line Data. The at least one data line Data is arranged on at least one side of the conductive structure 31 and/or the shield structure 32. The conductive structure 31 and the shield structure 32 are configured to transmit a power supply signal.

Preferably, a distance between the second conductive portion 312 and the data line Data is greater than or equal to 2 μm and less than or equal to 4 μm. Specifically, the distance between the second conductive portion 312 and the data line Data may be 2 μm, 2.5 μm, 3 μm, 3.5 μm or 4 μm. This can be set according to the actual situation.

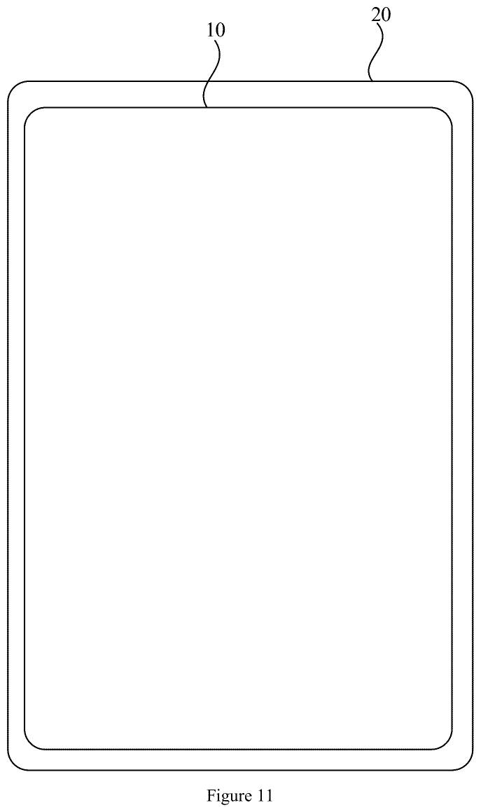

FIG. 11 is a schematic structural diagram of a display device according to an embodiment of the disclosure. On the basis of the above embodiments, and referring to FIG. 11, the display device 20 according to this embodiment includes a display panel 10 according to any of the above embodiments, and has the beneficial effects of the display panel 10 according to any of the above embodiments, which will not be described in detail herein.

It is to be noted that only preferred embodiments of the disclosure and the technical principles employed have been described above. Those skilled in the art will appreciate that the disclosure is not limited to the particular embodiments described herein and that various obvious changes, readjustments, and substitutions can be made to those skilled in the art without departing from the scope of protection of the disclosure. Therefore, although the disclosure has been described in detail through the above embodiments, the disclosure is not limited to the above embodiments, and can also include more other equivalent embodiments without departing from the concept of the disclosure, and the scope of the disclosure is determined by the scope of the appended claims.

What is claimed is:

1. A display panel, comprising:
a drive circuit layer;
a pixel defining layer arranged on a side of the drive circuit layer, the pixel defining layer comprising a plurality of pixel openings; and
a signal line layer arranged on a side of the pixel defining layer adjacent to the drive circuit layer,
wherein
the signal line layer comprises a plurality of conductive structures; and
the conductive structure is arranged centrosymmetrically in the pixel opening.

2. The display panel according to claim 1, wherein
an orthographic projection of the conductive structure on the drive circuit layer is located at least partially in an orthographic projection of the pixel opening on the drive circuit layer.

3. The display panel according to claim 1, wherein
the conductive structure is symmetric both in a first direction and in a second direction;
the first direction intersects with the second direction;
the first direction is perpendicular to the second direction;
the display panel further comprises a plurality of pixels, the drive circuit layer is connected to the plurality of pixels, and a light emitting layer of the pixel is arranged in the pixel opening; and the first direction is parallel to a row direction of the pixel and the second direction is parallel to a column direction of the pixel.

4. The display panel according to claim 1, wherein
the shape of the conductive structure comprises an “I” shape, a hollow square shape, or an “H” shape.

5. The display panel according to claim 1, wherein
the conductive structure comprises at least two first conductive portions and a second conductive portion;
the second conductive portion is connected between the at least two first conductive portions;
an extension direction of the first conductive portions is different from an extension direction of
the second conductive portion;
and
the first conductive portions have a width less than a width of the second conductive portion.

6. The display panel according to claim 5, wherein the second conductive portion is arranged centrally in a region defined by the pixel opening.

7. The display panel according to claim 6, further comprising a substrate, wherein the substrate is arranged on a side of the drive circuit layer away from the pixel defining layer;
the drive circuit layer further comprises:
a gate layer arranged on one side of the substrate; and
a capacitor layer arranged on a side of the gate layer away from the substrate; and
an orthographic projection of the second conductive portion on the substrate covers at least part of an orthographic projection of the capacitor layer on the substrate.

8. The display panel according to claim 7, wherein the drive circuit layer further comprises:
a gate bridge layer arranged on a side of the capacitor layer away from the substrate; and
the orthographic projection of the second conductive portion on the substrate covers at least part of an orthographic projection of the gate bridge layer on the substrate.

9. The display panel according to claim 8, wherein the signal line layer further comprises:
a plurality of shield structures connected to the conductive structures; and
an orthographic projection of the shield structure on the substrate does not overlap with an orthographic projection of the pixel opening on the substrate.

10. The display panel according to claim 9, wherein the orthographic projection of the shield structure on the substrate covers at least part of the orthographic projection of the gate bridge layer on the substrate.

11. The display panel according to claim 10, wherein the signal line layer further comprises:
at least one data line arranged on at least one side of at least one of the conductive structure and the shield structure; and
the conductive structure and the shield structure are configured to transmit a power supply signal.

12. The display panel according to claim 11, wherein a distance between the second conductive portion and the data line is greater than or equal to 2 μm and less than or equal to 4 μm.

13. The display panel according to claim 1, further comprising a plurality of pixels, wherein
the plurality of pixels comprises a plurality of pairs of pixels, the pair of pixels comprising a first pixel and a second pixel having the same luminous color and arranged adjacent to each other;
the conductive structure comprises a first conductive structure and a second conductive structure;
an orthographic projection of the first conductive structure on the drive circuit layer is located at least partially in an orthographic projection of the first pixel on the drive circuit layer;
an orthographic projection of the second conductive structure on the drive circuit layer is located at least partially in an orthographic projection of the second pixel on the drive circuit layer;
the first conductive structure and the second conductive structure are symmetrically arranged with respect to a first axis of symmetry; the first axis of symmetry is a perpendicular bisector of a line segment connecting a center of the first pixel and a center of the second pixel.

14. The display panel according to claim 13, wherein the first pixel and the second pixel are located in the same pixel row.

15. The display panel according to claim 14, wherein the display panel further comprises a plurality of third pixels having a luminous color different from the luminous color of the first pixel; and a pixel column in which the third pixel is located is arranged between a pixel column in which the first pixel is located and a pixel column in which the second pixel is located.

16. The display panel according to claim 15, wherein the luminous color of the first pixel and the second pixel is a first luminous color and the luminous color of the third pixel is a second luminous color; and the first pixel and the second pixel are located in adjacent columns of pixel columns having the first luminous color.

17. The display panel according to claim 16, wherein
the second conductive portion of the first conductive structure comprises a first sub-conductive portion and a second sub-conductive portion;
an orthographic projection of the first sub-conductive portion on the drive circuit layer is located in an orthographic projection of the first pixel of an n-th row on the drive circuit layer;
an orthographic projection of the second sub-conductive portion on the drive circuit layer is located in an orthographic projection of the first pixel of an (n+1)-th row on the drive circuit layer; and
n is a positive integer greater than or equal to 1.

18. The display panel according to claim 17, wherein when the first sub-conductive portion is arranged centrally in a region defined by the pixel opening, the second sub-conductive portion is arranged centrally in the region defined by the pixel opening; when the first sub-conductive portion is arranged on the left in the region defined by the pixel opening, the second sub-conductive portion is arranged on the right in the region defined by the pixel opening; and when the first sub-conductive portion is arranged on the right in the region defined by the pixel opening, the second sub-conductive portion is arranged on the left in the region defined by the pixel opening.

19. A display panel, comprising:
a drive circuit layer;
a pixel defining layer arranged on a side of the drive circuit layer, the pixel defining layer comprising a plurality of pixel openings; and
a signal line layer arranged on a side of the pixel defining layer adjacent to the drive circuit layer,
wherein
the signal line layer comprises a plurality of conductive structures;
the conductive structure divides the pixel opening into at least two light exit areas in the pixel opening; and exit light intensities of the light exit areas on two sides of the conductive structure are balanced in a preset direction.

20. A display device, comprising a display panel of claim 1.
